(19) United States
(12) Patent Application Publication
(10) Pub. No.: US 2024/0274441 A1
(43) Pub. Date: Aug. 15, 2024

(54) SEMICONDUCTOR DEVICE AND METHODS FOR FORMING THE SAME

(71) Applicant: Winbond Electronics Corp., Taichung City (TW)

(72) Inventors: Wei-Nan CHUANG, Taichung City (TW); Yu-Ting HUANG, Taichung City (TW); Yi-Chung CHEN, Taichung City (TW)

(21) Appl. No.: 18/310,693

(22) Filed: May 2, 2023

(30) Foreign Application Priority Data
Feb. 9, 2023 (TW) 112104552

(51) Int. Cl. H01L 21/321; H01L 21/3105; H01L 29/423; H10B 41/10; H10B 41/30; H10B 41/43

(52) U.S. Cl. CPC H01L 21/3212; H01L 21/31053; H01L 29/42324; H10B 41/10; H10B 41/30; H10B 41/43

(57) ABSTRACT

A method for forming a semiconductor device includes providing a substrate that has a first region and a second region adjacent to the first region; forming several first components on the substrate and in the first region, and forming a second component on the substrate and in the second region; forming a first material layer over the first components to cover the first components; and forming a patterned dummy layer that is embedded in the first material layer; forming a second material layer over the second component to cover the second component; and performing a polishing process on the first material layer and the second material layer simultaneously. The second material layer and the first material layer include different materials.

### CROSS REFERENCE TO RELATED APPLICATIONS

This Application claims priority of Taiwan Patent Application No. 112104552, filed on Feb. 9, 2023, the entirety of which is incorporated by reference herein.

### BACKGROUND

### Technical Field

The disclosure relates to a semiconductor device and methods for forming the same, and it relates to a semiconductor device that includes different material layers with flat and coplanar top surfaces after a polishing process is applied to the material layers.

### Description of the Related Art

Methods for manufacturing semiconductor devices typically include one or more planarization processes to remove a suitable amount of the associated material layers. The remaining portions of the associated material layers generally have flat top surfaces.

However, when a planarization process such as a chemical mechanical polishing (CMP) process is performed on different material layers, the slurry may have different polishing rates on the different materials. After the planarization process is performed, the top surface of one of the material layers tends to show the defect of a dishing profile or a protruding profile relative to the other material layer. Therefore, it is difficult to make the top surfaces of the different material layers coplanar after the planarization process is performed. Thus, the electronic properties of the components that are made by or formed on these material layers will be affected. The electrical performance of the resulting semiconductor device will be decreased due to the above-mentioned problem.

### SUMMARY

Some embodiments of the present disclosure provide a method for forming a semiconductor device. First, a substrate that has a first region and a second region adjacent to the first region is provided. Several first components are formed over the substrate and in the first region. One or more second components are formed over the substrate and in the second region. Then, a first material layer is formed over the first components to cover the first components. A patterned dummy layer that is embedded in the first material layer is formed. A second material layer is formed over the second component to cover the second component, wherein the second material layer and the first material layer include different materials. Next, a polishing process is performed on the first material layer and the second material layer simultaneously.

Some embodiments of the present disclosure provide a semiconductor device. The semiconductor device includes a substrate having a first region and a second region adjacent to the first region; several first components formed over the substrate and in the first region; a second component formed over the substrate and in the second region; a first material layer formed over the first components and covers the first components; a second material layer formed over the second component and covers the second component, wherein the second material layer and the first material layer include different materials; a patterned dummy layer formed over the first components and is embedded in the first material layer.

### BRIEF DESCRIPTION OF THE DRAWINGS

FIG. 1, FIG. 2, FIG. 3, FIG. 4, FIG. 6 and FIG. 7 illustrate cross-sectional views of intermediate stages of a semiconductor device in accordance with some embodiments of the present disclosure.

FIG. 5A and FIG. 5B are top views of a portion of a patterned dummy layer in accordance with some embodiments of the present disclosure.

FIG. 8 is a cross-sectional view of an intermediate stage of a semiconductor device in accordance with some other embodiments of the present disclosure.

FIG. 9A and FIG. 9B are cross-sectional views of intermediate stages of a semiconductor device in accordance with some embodiments of the present disclosure.

### DETAILED DESCRIPTION

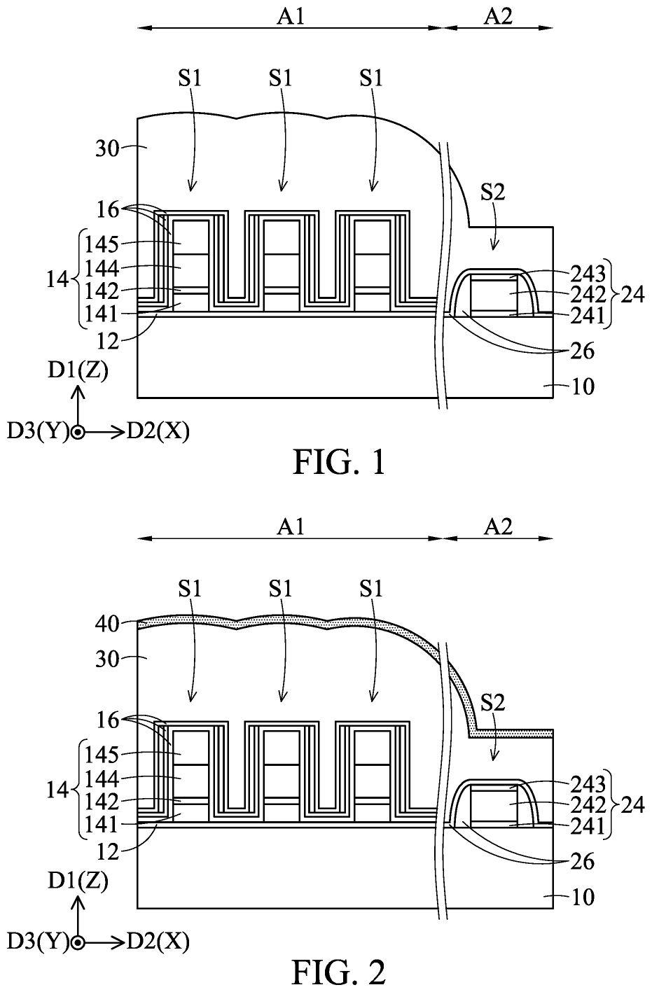

Referring to FIG. 1, a substrate 10 is provided. The substrate 10 includes a first region A1 and a second region A2 adjacent to the first region A1. For example, the first region A1 may be an array region or a memory cell region. The second region A2 may be a peripheral region.

Next, several semiconductor components are formed over the substrate 10. For example, the semiconductor components may include first components S1 in the first region A1 and one or more second components S2 in the second region A2.

In this embodiment, each of the first components S1 includes several material layers that are vertically stacked in the first direction D1 (such as Z direction). The first components S1 and the second components S2 are separated from each other in the second direction D2 (such as X direction). Each of the first components S1 and the second components S2 extends in the third direction D3 (such as Y direction).

In some embodiments, the first components S1 are gate structures of a flash memory. A tunnel dielectric layer 12 can be formed on the substrate 10, and the first components S1 can be formed on the tunnel dielectric layer 12.

In some embodiments, the first components S1 are first gate structures 14. Each of the first gate structures 14 may include a floating gate 141, an inter-gate dielectric layer 142, a control gate 144 and a capping dielectric 145 that are sequentially stacked over the substrate 10.

In some embodiments, spacers 16 are further formed on the sidewalls of the first components S1. The spacers 16 may be a single-layer structure or a multilayer structure that includes one of more of insulating materials, such as silicon oxide, silicon nitride, silicon oxynitride, or another suitable material.

In some embodiments, the second components S2 are second gate structures 24, such as planar gate structures. Each of the second gate structures 24 may include, for example, a gate dielectric layer 241, a gate electrode 242 and a hard mask 243 that are sequentially formed over the substrate 10.

In addition, the spacers 26 that include a single or multi-layer insulating material layers may be formed on the sidewalls of each of the second components S2.

Afterwards, the first material 30 is formed over and cover the first components S1 and the second components S2. The first material 30 also fills the gaps between the first components S1 and the second components S2. Since the density of the semiconductor components in the first region A1 is higher than that in the second region A2, the top surface of the first material 30 in the first region A1 is higher than that in the second region A2. However, this disclosure is not limited to the aforementioned condition.

In some embodiments, the first material 30 includes one or more conductive materials, such as polysilicon or another suitable conductive material. The first material 30 can be deposited by a chemical vapor deposition (CVD) process, an atomic layer deposition (ALD) process, a physical vapor deposition (PVD) process, another suitable process, or a combination of the aforementioned processes.

Referring to FIG. 2, a dummy layer 40 is formed on the first material 30. The dummy layer 40 may be formed above the first components S1 and the second components S2.

The dummy layer 40 can be a single-layer structure or a multi-layer structure. In some embodiments, the dummy layer 40 includes an oxide layer and can be formed by a CVD process, an atomic layer deposition process, or another suitable method. The CVD process is, for example, a high-density plasma chemical vapor deposition (HDPCVD), an atmospheric pressure chemical vapor deposition (APCVD), a low pressure chemical vapor deposition (LPCVD), or a plasma enhanced chemical vapor deposition (PECVD). In some examples, the dummy layer 40 includes silane oxide, such as tetraethoxysilane (TEOS), and is formed by CVD.

Referring to FIG. 3, the dummy layer 40 is patterned by performing a patterning process to form a patterned dummy layer 41. In this embodiment, only the portion of the dummy layer 40 in the first region A1 is patterned. The other portion of the dummy layer 40 in the second region A2 is not patterned. However, the disclosure is not limited thereto. Therefore, in this example, the patterned dummy layer 41 includes a first portion 411 with a pattern in the first region A1 and a second portion 412 without a pattern in the second region A2. The second portion 412 may be a continuous portion. The first portion 411 is formed above the first components S1, and the second portion 412 is formed above the second components S2. Specifically, after the patterning process is performed, the dummy layer 40 is divided into several sections and those sections collectively are referred to as the patterned dummy layer 41.

In some embodiments, when the patterning process is performed, the portions of the dummy layer 40 in the first region A1 are removed, and the portions of the first material 30 that are correspondingly the removed portions of the dummy layer 40 are also removed, thereby to form the first material 310. Specifically, the patterned first material 310 includes a portion 311 with a pattern in the first region A1 and a portion 312 without a pattern in the second region A2.

The above-mentioned patterning process can be performed by lithography process and etching process to remove portions of the dummy layer 40. The patterning process may further remove portions of the first material 30 under the dummy layer 40. Specifically, a patterned photoresist layer is formed on the dummy layer 40 through a lithography process. Then, according to the patterned photoresist layer, the portions of the dummy layer 40 that are not covered by the patterned photoresist layer are etched. The etching process is, for example, a dry etching process, a wet etching process, a plasma etching process, a reactive ion etching (RIE) process, or another suitable process. In this embodiment, a dry etching process is performed on the dummy layer 40 to expose a portion of the first material 30 in the first region A1.

As shown in FIG. 3, after the patterning process is performed, the patterned dummy layer 41 includes several holes 45 that penetrate the dummy layer 40 and extend into the first material 30 in the first direction D1. In some embodiments, the widths of the holes 45 in the first portion 411 of the patterned dummy layer 41 are substantially the same as the widths of the recesses in the portion 311 of the patterned first material 310. However, the present disclosure is not limited thereto. In other embodiments, each of the holes 45 may have a tapered section with a wide top and a narrow bottom.

Referring to FIG. 4, a second material 313 is formed over the patterned first material 310 and the patterned dummy layer 41. The second material 313 covers the patterned dummy layer 41 and fills the holes 45. Therefore, the second material 313 and the patterned first material 310 are collectively referred to as a first material layer 31. The patterned dummy layer 41 is embedded in the first material layer 31.

In some embodiments, the second material 313 includes one or more conductive materials. The second material 313 and the first material 30 may include different materials or the same material. In one embodiment, the method for forming the second material 313 is the same as the method for forming the first material 310.

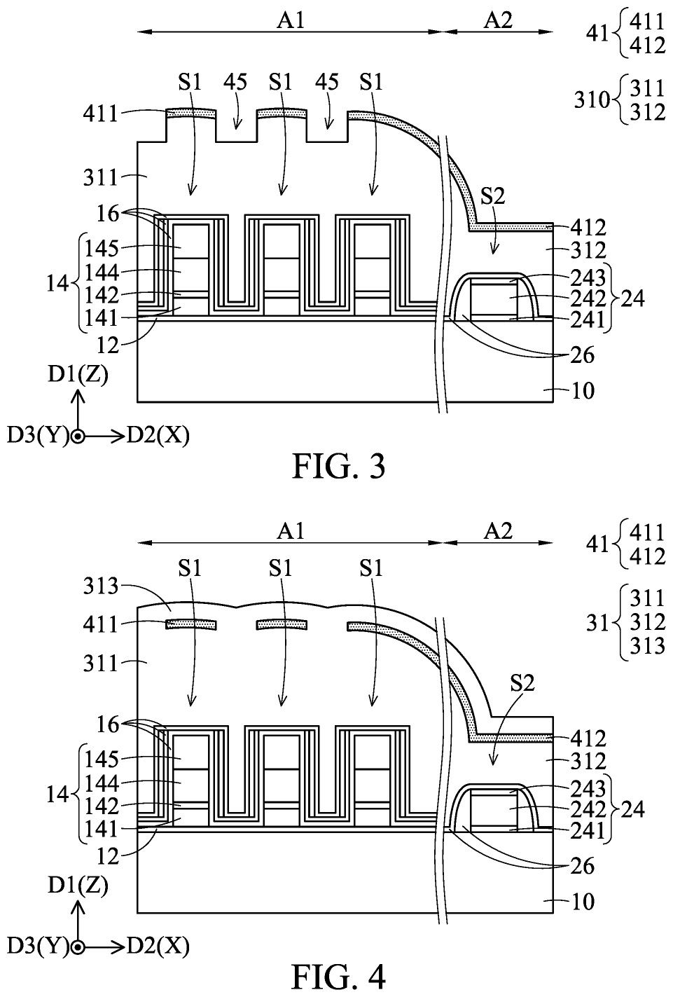

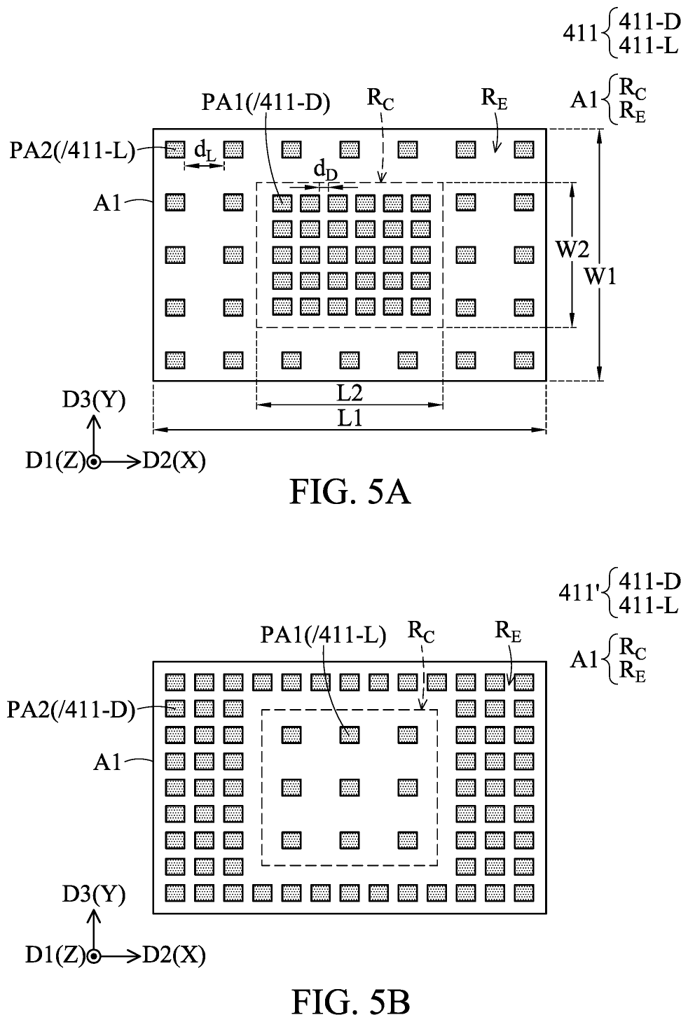

As shown in FIG. 4, FIG. 5A or FIG. 5B, it should be noted that the portion of the patterned dummy layer 41 in the first region A1 includes a pattern portion with different pattern distribution densities. When a planarization step is performed subsequently, the polishing rates of different materials can be adjusted through the pattern portion of the patterned dummy layer 41. Therefore, the remaining portions of different material layers have coplanar top surfaces after a planarization step is performed. The details of the patterned dummy layer 41 and its effect on the polishing rates of different materials of some embodiments are provided in the following descriptions.

Referring to FIG. 6, a second material layer 50 is formed over the first material layer 31 and covers the second components S2. The second material layer 50 may include one or more insulating material layers, such as oxide layer or another suitable material. In one embodiment, the second material layer 50 and the first material layer 31 include different materials. For example, the first material layer 31 includes polysilicon, and the second material layer 50 includes silicon oxide.

The second material layer 50 can be formed by performing a CVD process or another suitable deposition method. In some embodiments, the liquid spin-on glass (SOG) material can be uniformly coated on the substrate 10 by a spin-on coating method. The liquid SOG material can be cured at a high temperature to remove the solvent, thereby forming a second material layer 50 with characteristics similar to silicon dioxide.

In some embodiments, the second material layer 50 and the dummy layer 40 include the same material. In some embodiments, the densities of the materials of the second material layer 50 and the dummy layer 40 are different, and/or the harnesses of the materials of the second material layer 50 and the dummy layer 40 are different. In some embodiments, the second material layer 50 is a silicon oxide layer with a low density, and the dummy layer 40 is a silicon oxide layer with a high density. In some examples, the dummy layer 40 has a first hardness, and the second material layer 50 has a second hardness. The first hardness is greater than the second hardness.

In other embodiments, before the step of forming the second material layer 50 as shown in FIG. 6, the method may include another process. For example, a silicon nitride layer (not shown) is deposited over the first material layer 31 shown in FIG. 4, and then all material layers in the second region A2 are removed to expose the second components S2. Next, the spacers at the sidewalls of the second components S2 are formed. Then, a SOG layer is deposited over the entire surface of the substrate 10. A CMP process is performed on the SOG layer and stop at the silicon nitride layer. Accordingly, the silicon nitride layer is exposed in the first region A1, and the SOG layer is exposed in the second region A2. Next, the silicon nitride layer is removed, so that the portion 311 (polysilicon) of the first material layer 31 is exposed in the first region A1, while the SOG layer is still exposed in the second region A2. Next, the portion 311 of the first material layer 31 in the first region A1 and the SOG layer in the second region A2 are subjected to a polishing process as shown in FIG. 7.

Referring to FIG. 7, after the second material layer 50 is formed (FIG. 6), a planarization process is performed on the first material layer 31 and the second material layer 50. For example, a polishing process can be performed by using a suitable slurry. In one embodiment, the polishing process is a CMP process. Since the second material layer 50 and the first material layer 31 include different materials, the slurry has different polishing rates on the different materials.

In the conventional manufacturing method, after a polishing process is performed on the different materials in different regions, one of the materials is more recessed or more protruded than the other material due to the selectivity of polishing rates of the slurry for different materials. Therefore, the flatness of the top surfaces of the different materials after polishing cannot be achieved by the conventional manufacturing method. In particular, the larger an array region or a memory cell region (i.e. the first region A1) is and the closer of a portion of the material layer it is to the center, the more severe the recession or protrusion of the material layer. According to the patterned dummy layer 41 with a suitable pattern in some embodiments of the present disclosure, the polishing rates of different materials can be adjusted through the pattern of the patterned dummy layer 41 by using a slurry with suitable selectivity of polishing rates for different materials. Therefore, the flatness and coplanarity of the top surfaces of the different materials after polishing can be achieved.

Please refer to FIG. 5A and FIG. 7. FIG. 5A is a top view of a portion of a patterned dummy layer in some embodiments of the present disclosure. When a slurry that has a faster polishing rate on the first material layer 31 than on the second material layer 50/the dummy layer 40 is selected, the pattern of the first portion 411 of the patterned dummy layer 41 in the first region A1 as shown in FIG. 5A can be implemented for adjusting the polishing rates of the different materials. The first portion 411 of the patterned dummy layer 41 includes first pattern portions PA1 and second pattern portions PA2, as viewed from the top of the substrate 10. The first pattern portions PA1 are arranged in the central region R_{C} of the first region A1. The second pattern portions PA2 are arranged in the edge region R_{E} of the first region A1.

In FIG. 5A, the first pattern portions PA1 include several patterns 411-D and the second pattern portions PA2 include several pattern 411-L. The pattern distribution density of the patterns 411-D is greater than that of the patterns 411-L. There is a first distance d_{D} between two adjacent patterns 411-D, and there is a second distance d_{L} between two adjacent patterns 411-L. The first distance d_{D}is less than the second distance d_{L}.

According to some embodiments, a slurry that has a faster polishing rate on the first material layer 31 than on the second material layer 50 is selected. When a polishing process is performed simultaneously on the first material layer 31 (such as polysilicon) in the first region A1 and the second material layer 50 (such as SOG) in the second region A2, the first portion 411 of the patterned dummy layer functions as a buffer, so that the polishing rate for the first material layer 31 in the first region A1 (that would be concave after polishing without forming the first portion 411) is decreased when the slurry is in contact with the first portion 411. Therefore, the first portion 411 of the patterned dummy layer equalizes the polishing rates on the first material layer 31 in the first region A1 and the second material layer 50 in the second region A2. That is, the remaining portions of the first material layer 31 and the second material layer 50 have flat top surfaces after polishing. The top surface of the remaining portion of the first material layer 31 is level with the top surface of the remaining portion of the second material layer 50 after polishing.

In addition, as shown in FIG. 5A, the patterns 411-D of the first portion 411 that are arranged more densely in the central region R_{C} of the first region A1 can be used as buffering components. Conventionally, the portion of the first material layer 31 in the central region R_{C} would be seriously concave after polishing since no patterns 411-D are formed in the first material layer 31. In this embodiment, the patterns 411-D provide a buffering effect for the portion of the first material layer 31 in the central region R_{C}, so that the top surfaces of the remaining portions of the first material layer 31 and the second material layer 50 are flat and level with each other after polishing.

Referring to FIG. 7, when a portion of the first material layer 31 and a portion of the second material layer 50 are removed by the slurry to reach a polishing target position L_{Target}, the top surface 32a of the remaining portion 32 of the first material layer 31 is substantially coplanar with the top surface 51a of the remaining portion 51 of the second material layer 50. In addition, the top surfaces 32a and 51a are flat surfaces. In this embodiment, the remaining portion 32 of the first material layer 31 includes a portion 321 in the first region A1 and a portion 322 in the second region A2. The portion 322 is located under the remaining portion of the second material layer 50, and thus is not subjected to the polishing process.

Referring to FIG. 5A, the first region A1 has a length L1 in the second direction D2 and a width W1 in the third direction D3, and the central region R_{C} has a length L2 in the second direction D2 and a width W2 in the third direction D3. In some embodiments, the length L2 can be in the range of 0.3×L1 to 0.6×L1; for example, L2 is approximately equal to 0.5×L1, but the present disclosure is not limited thereto. By adjusting the length ratio and/or the width ratio of the central region R_{C} relative to the first region A1, the occupied area of the patterns 411-D can be altered to provide a more appropriate buffering effect. Accordingly, the polishing rates can be precisely controlled, thereby obtaining more flat top surfaces of the remaining portions of the material layer 31 and the second material layer 50 after polishing.

In addition, the first pattern portion PA1 and the second pattern portion PA2 in FIG. 5A are regularly distributed patterns (for example, there are substantially equal first distances d_{D} between two adjacent patterns 411-D and equal second distances d_{L} between two adjacent patterns 411-L), but the distances between the adjacent patterns can also be gradually changed. In other embodiments, the patterns 411-D that are closer to the center of the central region R_{C} are arranged more closely, and the patterns 411-L that are closer to the periphery of the edge region R_{E} are arranged more loosely. Alternatively, the patterns of the first pattern portion PA1 and the second pattern portion PA2 may be arranged in a non-array arrangement or randomly distributed.

Referring to FIG. 5B and FIG. 7. FIG. 5B is a top view of a portion of a patterned dummy layer in some embodiments of the present disclosure. When a slurry that has a faster polishing rate on the second material layer 50 than on the first material layer 31 is selected, the pattern of the first portion 411′ of the patterned dummy layer 41 in the first region A1 as shown in FIG. 5B can be implemented for adjusting the polishing rates of the different materials. In some embodiments, the first portion 411′ of the patterned dummy layer 41 includes first pattern portions PA1 and second pattern portions PA2, as viewed from the top of the substrate 10. The first pattern portions PA1 are arranged in the central region R_{C} of the first region A1. The second pattern portions PA2 are arranged in the edge region R_{E} of the first region A1.

In FIG. 5B, the first pattern portion PA1 includes several pattern 411-L and the second pattern portion PA2 includes several pattern 411-D. The pattern distribution density of the patterns 411-L is less than that of the patterns 411-D. The distance between two adjacent patterns 411-L is greater than the distance between two adjacent patterns 411-D.

According to some embodiments, if a slurry that has a faster polishing rate on the second material layer 50 than on the first material layer 31 is selected when a polishing process is performed simultaneously on the first material layer 31 (such as polysilicon) in the first region A1 and the second material layer 50 (such as SOG) in the second region A2, the patterned dummy layer 41 functions as a buffer, so that the polishing rate for the second material layer 50 in the second region A2 is decreased. Therefore, the patterned dummy layer 41 equalizes the polishing rates for the first material layer 31 in the first region A1 and the second material layer 50 in the second region A2. That is, the remaining portions of the first material layer 31 and the second material layer 50 have flat top surfaces after polishing. The top surface of the remaining portion of the first material layer 31 is level with the top surface of the remaining portion of the second material layer 50 after polishing.

As shown in FIG. 5B, compared with the edge region R_{E}, the patterns 411-L of the first portion 411 that are arranged more loosely in the central region R_{C} of the first region A1 can be used as buffering components. Conventionally, the portion of the first material layer 31 in the central region R_{C} would be seriously protruded after polishing since no patterns 411-L are formed in the first material layer 31. In this embodiment, the patterns 411-L and 411-D in FIG. 5B function as buffering components and provide a better polishing effect for the portion of the first material layer 31 in the central region R_{C}. Therefore, the top surfaces of the remaining portions of the first material layer 31 and the second material layer 50 are more flat and level with each other after polishing.

According to the above-mentioned embodiment, when a portion of the first material layer 31 and a portion of the second material layer 50 are removed by the slurry to reach a polishing target position L_{Target}, the top surface 32a of the remaining portion 32 of the first material layer 31 is substantially coplanar with the top surface 51a of the remaining portion 51 of the second material layer 50, as shown in the FIG. 7.

In addition, in FIG. 5B, although there are substantially equal distances between two adjacent patterns 411-D of the first pattern portion PA1 and equal distances between two adjacent patterns 411-L of the second pattern portion PA2, the distances between two adjacent patterns can also be gradually increased or decreased. In other embodiments, the patterns 411-L that are closer to the center of the central region R_{C} are arranged more loosely, and the patterns 411-D that are closer to the periphery of the edge region R_{E} are arranged more closely. Alternatively, the patterns of the first pattern portion PA1 and the second pattern portion PA2 may be arranged in a non-array arrangement or randomly distributed.

Refer to FIG. 6 and FIG. 7. The patterned dummy layer 41 includes the marking portion 421 adjacent to the boundary L_{IN} between the first region A1 and the second region A2. The marking portion 421 is under the polishing target position L_{Target}. Specifically, after the polishing process is performed to remove the first portion 411 of the patterned dummy layer 41, the marking portion 421 is left in the first region A1 and the portion 422 is left in the second region A2. In some embodiments, the marking portion 421 extends from the first region A1 to the second region A2, and continuously crosses the boundary L_{IN} to connect the remaining portion 422 that is left in the second region A2.

In other embodiments, the patterned dummy layer 41 has no marking portion. That is, after the polishing process is performed, the first portion 411 of the patterned dummy layer 41 in the first region A1 is completely removed without leaving any portion.

Although the above-mentioned embodiments are implemented by using a suitable slurry and a single-stage polishing process, the present disclosure is not limited thereto. In other embodiments, more suitable slurries and multi-stage polishing processes can be selected and implemented.

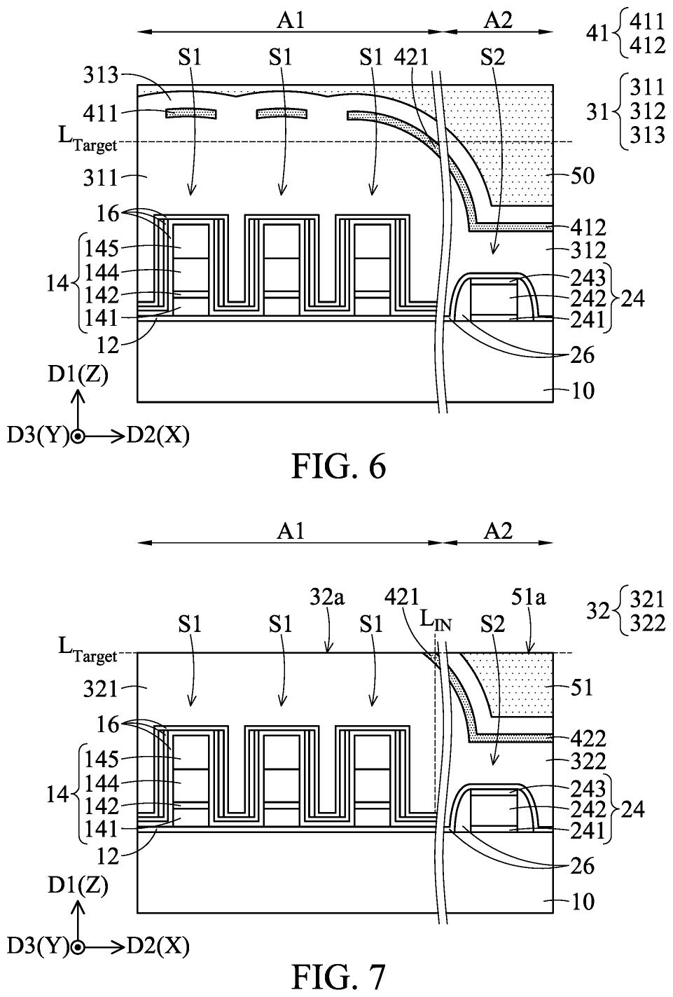

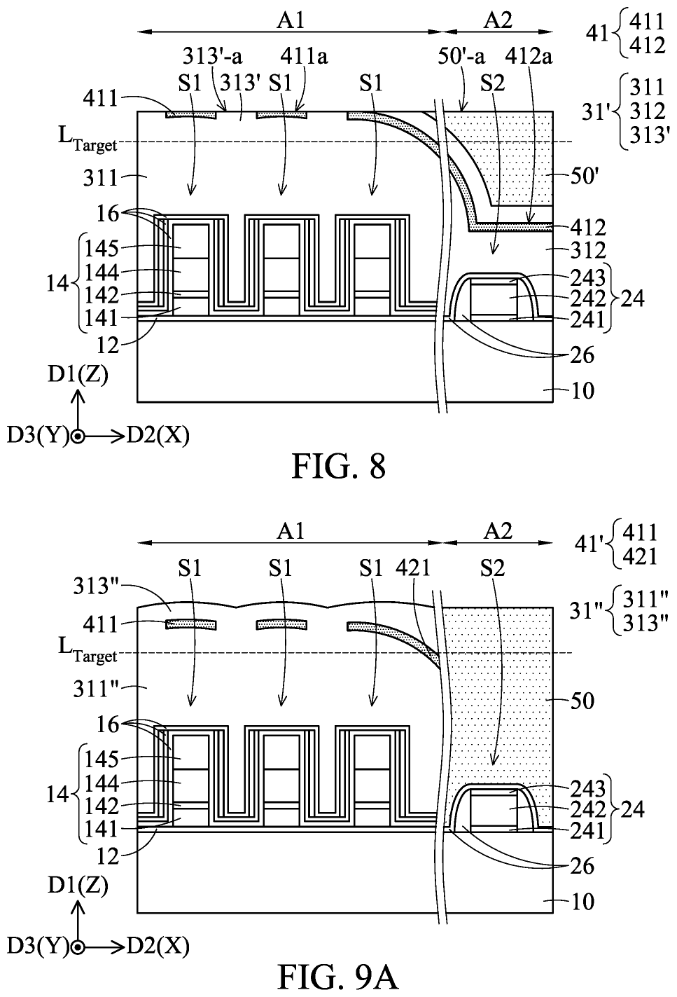

FIG. 8 is a cross-sectional view of an intermediate stage of a semiconductor device during a polishing process in some embodiments of the present disclosure. The features in FIG. 8 similar or identical to the features in FIG. 1-FIG. 7 are designated with similar or the same reference numbers. Details of the configurations, materials and manufacturing method of the components shown in FIG. 8 can be referred to the above-mentioned descriptions of the related contents in FIG. 1 to FIG. 7, and are not repeated herein for the sake of simplicity and clarity.

A step shown in FIG. 8 can be additionally performed between the steps shown in FIG. 6 and FIG. 7. The first material layer 31 and the second material layer 50 are polishing in two stages. In some embodiments, the polishing step in the first stage is in an endpoint detection (EPD) mode, and the polishing step in the second stage is in a time mode.

At first, a structure as shown in FIG. 6 is provided. Next, referring to FIG. 6 and FIG. 8, the polishing step in the first stage is performed by using the first portion 411 of the patterned dummy layer 41 as a stop layer to remove a portion of the second material layer 50 and a portion of the first material layer 31. Therefore, the top surface 411a of the first portion 411 of the patterned dummy layer 41 is exposed after the polishing step in the first stage is performed. That is, according to an endpoint detection system of the embodiment, the polishing endpoint of the first stage is set on the first portion 411 of the patterned dummy layer 41.

After the polishing step in the first stage is performed, the patterned first material layer 31′ includes a portion 311 with a pattern in the first region A1, a portion 312 without a pattern in the second region A2, and the remaining portion 313′ of the second material 313. At this time, the patterned dummy layer 41 has not been removed, or only a small portion of the first portion 411 has been removed. In addition, the second material layer 50 in the second region A2 is also polished to be approximately level with the first portion 411. In this embodiment, the top surface 411a of the patterned dummy layer 41, the top surface 313′-a of the remaining portion 313′ of the second material 313, and the top surface 50′-a of the remaining portion 50′ of the second material layer are substantially coplanar.

During the polishing step in the first stage, the flatness of the top surface of the patterned first material layer 31′ and the remaining portion 50′ of the second material layer can be improved by selecting a suitable first slurry, which has different polishing rates on the first material layer 31 and the second material layer 50, and implementing the patterns of the first portion 411 or 411′ of the patterned dummy layer 41 shown in FIG. 5A or FIG. 5B.

Next, a polishing step in the second stage is performed. By setting the polishing time, such as polishing for a few seconds, a second slurry is implemented to polish the patterned first material layer 31′ and the remaining portion 50′ of the second material layer until reaching the polishing target position L_{Target} and forming a structure shown in FIG. 7.

In some embodiments, the composition of the second slurry is different from the composition of the first slurry.

In this embodiment, since a portion of the first material layer 31 and a portion of the second material layer 50 have been removed by the polishing step in the first stage (i.e. the EPD mode), only small portions of the first material layer 31 and the second material layer 50 need to be removed to reach the polishing target position. Accordingly, the polishing step in the second stage is less likely to cause the problem of concave or protruding surface of the material layer due to long-time polishing. Therefore, the selection of the second slurry that is used in the second stage is not limited by the selectivity of the polishing rates to the first material layer 31 and the second material layer 50. In one example, the selectivity of the polishing rates to the first material layer 31 and the second material layer 50 that does not exceed 10 can be implemented during the polishing process in the second stage.

In other embodiments, after the structure shown in FIG. 4 is formed, all of the portions of the first material layer 31 and the patterned dummy layer 41 in the second region A2 can be further removed to expose the second components S2. Then, the second material layer 50 is deposited in the second region A2, and a polishing process is performed on the first material layer 31 and the second material layer 50 subsequently.

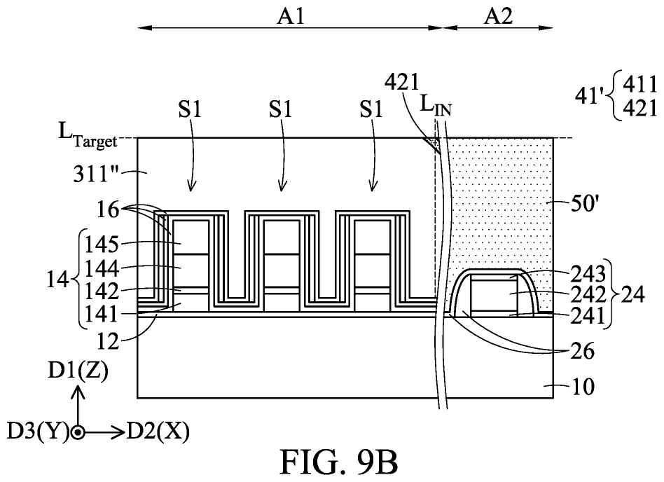

Refer to FIG. 4, FIG. 9A and FIG. 9B. FIG. 9A and FIG. 9B are cross-sectional views of intermediate stages of a semiconductor device in some embodiments of the present disclosure. The features in FIG. 9A and FIG. 9B similar or identical to the features in FIG. 4, FIG. 6 and FIG. 7 are designated with similar or the same reference numbers. Details of the configurations, materials and manufacturing method of the components shown in FIG. 9A and FIG. 9B can be referred to the above-mentioned descriptions of the related contents in FIG. 4, FIG. 6 and FIG. 7, and are not repeated herein for the sake of simplicity and clarity.

At first, a structure as shown in FIG. 4 is provided. Afterwards, the portions 312 and 313 of the first material layer 31 and the second portion 412 of the patterned dummy layer 41 in the second region A2 are removed to expose the substrate 10 and the second components S2. Next, a second material layer 50 is deposited in the second region A2 to cover the substrate 10 and the second components S2. After this removal step, a first material layer 31″ includes the portions 311″ and 313″ in the first region A1, and the patterned dummy layer 41′ includes the first portion 411 and the marking portion 421 in the first region A1.

In some embodiments, the marking portion 421 is located in the first region A1, and is correspondingly adjacent to the boundary L_{IN} between the first region A1 and the second region A2. Part or all of the marking portion 421 is left below the polishing target position L_{Target}. After the polishing process is performed subsequently, the marking portion 421 will remain in the first region A1 and be adjacent to the boundary L_{IN}. In other embodiments, the marking portion 421 may be left above the polishing target position L_{Target}.

Next, a planarization process is performed on the first material layer 31″ and the second material layer 50 simultaneously to form the structure shown in FIG. 9B. Details of the planarization process are essentially the same as what have been discussed above, and are not repeated herein.

According to some embodiments, when the polishing process is performed to reach the polishing target position L_{Target}, the marking portion 421 will be left in the first region A1. In other words, after the polishing process is performed, the remaining portion 311″ of the first material layer exposes the marking portion 421 adjacent to the boundary L_{IN} between the first region A1 and the second region A2.

According to the aforementioned descriptions, the polishing rates of different materials can be appropriately adjusted by embedding a patterned dummy layer in the material layer, in some embodiments of the present disclosure. Therefore, the remaining portions of different material layers have flat top surfaces when a planarization process is performed on the different material layers. Accordingly, even the a slurry has different polishing rates on different materials, after the method of forming a patterned dummy layer of the embodiment is implemented and a planarization step is then performed on the material layers simultaneously, the remaining portions of different material layers have flat and coplanar top surfaces. In addition, the patterned dummy layer may also have pattern portions with different pattern distribution densities, so as to achieve a better polishing and planarization effect. Therefore, the method of the embodiments solves the conventional problem that the top surface of one of the material layers tends to be relatively concave or protruding when different material layers are polished. According to the embodiments of the present disclosure, different material layers with flat top surfaces can be provided after the planarization process, so that the components that are subsequently fabricated on these material layers have good electronic properties, thereby improving the electrical performance of the fabricated semiconductor device. In addition, a method for manufacturing the patterned dummy layer in some embodiments is simple and compatible with existing manufacturing processes. Thus, formation of the patterned dummy layer of the embodiments does not increase production costs and is suitable for mass production.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
providing a substrate that has a first region and a second region adjacent to the first region;
forming a plurality of first components over the substrate and in the first region, and forming a second component over the substrate and in the second region;
forming a first material layer over the first components to cover the first components;
forming a patterned dummy layer that is embedded in the first material layer;
forming a second material layer over the second component, wherein the second material layer and the first material layer comprise different materials; and
performing a polishing process on the first material layer and the second material layer simultaneously.

2. The method for forming a semiconductor device as claimed in claim 1, wherein the polishing process comprises:
removing a portion of the first material layer and a portion of the second material layer,
wherein a top surface of a remaining portion of the first material layer is coplanar with a top surface of a remaining portion of the second material layer.

3. The method for forming a semiconductor device as claimed in claim 1, wherein the polishing process comprises:
removing a portion of the first material layer by using the patterned dummy layer as a stop layer, and exposing the patterned dummy layer; and
removing another portion of the first material layer and a portion of the second material layer, wherein a top surface of a remaining portion of the first material layer is coplanar with a top surface of a remaining portion of the second material layer.

4. The method for forming a semiconductor device as claimed in claim 3, further comprising:
providing a first slurry to remove the portion of the first material layer and expose the patterned dummy layer; and
providing a second slurry to remove the other portion of the first material layer and the portion of the second material layer, so that the top surface of the remaining portion of the first material layer is coplanar with the top surface of the remaining portion of the second material layer,
wherein the first slurry is different from the second slurry.

5. The method for forming a semiconductor device as claimed in claim 1, wherein the patterned dummy layer comprises first pattern portions and second pattern portions, and the first pattern portions and the second pattern portions are respectively arranged in a central region and an edge region of the first region of the substrate, wherein a pattern distribution density of the first pattern portions is greater than a pattern distribution density of the second pattern portions.

6. The method for forming a semiconductor device as claimed in claim 5, wherein a slurry has a faster polishing rate on the first material layer than on the second material layer.

7. The method for forming a semiconductor device as claimed in claim 1, wherein the patterned dummy layer comprises first pattern portions and second pattern portions, and the first pattern portions and the second pattern portions are respectively arranged in a central region and an edge region of the first region of the substrate, wherein a pattern distribution density of the first pattern portions is less than a pattern distribution density of the second pattern portions.

8. The method for forming a semiconductor device as claimed in claim 7, wherein a slurry has a faster polishing rate on the second material layer than on the first material layer.

9. The method for forming a semiconductor device as claimed in claim 1, wherein the patterned dummy layer comprises:
a marking portion in the first region and adjacent to a boundary between the first region and the second region.

10. The method for forming a semiconductor device as claimed in claim 9, wherein after the polishing process is performed, the marking portion that is in the remaining portion of the first material layer and adjacent to the boundary between the first region and the second region is exposed.

11. The method for forming a semiconductor device as claimed in claim 1, wherein forming the first material layer and forming the patterned dummy layer comprises:
forming a first material over the first components to cover the first components;
forming a dummy layer over the first material;
patterning the dummy layer to form the patterned dummy layer; and
forming a second material over the first material and the patterned dummy layer, wherein the second material covers the patterned dummy layer,
wherein the second material and the first material collectively form the first material layer.

12. A semiconductor device, comprising:
a substrate having a first region and a second region adjacent to the first region;
a plurality of first components formed over the substrate and in the first region;
a second component formed over the substrate and in the second region;
a first material layer formed over the first components;
a second material layer formed over the second component, wherein the second material layer and the first material layer comprise different materials;
a patterned dummy layer formed over the first components, wherein the patterned dummy layer is embedded in the first material layer.

13. The semiconductor device as claimed in claim 12, wherein the patterned dummy layer comprises first pattern portions and second pattern portions, and the first pattern portions and the second pattern portions are respectively arranged in a central region and an edge region of the first region of the substrate, wherein a pattern distribution density of the first pattern portions is greater than a pattern distribution density of the second pattern portions.

14. The semiconductor device as claimed in claim 12, wherein the patterned dummy layer comprises first pattern portions and second pattern portions, and the first pattern portions and the second pattern portions are respectively arranged in a central region and an edge region of the first region of the substrate, wherein a pattern distribution density of the first pattern portions is less than a pattern distribution density of the second pattern portions.

15. The semiconductor device as claimed in claim 12, wherein the patterned dummy layer further extends to the second region, and the patterned dummy layer is disposed over the second component.

16. The semiconductor device as claimed in claim 15, wherein the first material layer further extends to the second region and the first material layer is disposed over the second component, wherein the patterned dummy layer further comprises:
a continuous portion, correspondingly disposed in the second region and embedded in the first material layer,
wherein the second material layer is formed over the continuous portion of the patterned dummy layer and a portion of the first material layer.

17. The semiconductor device as claimed in claim 12, wherein the patterned dummy layer comprises:
a marking portion in the first region and adjacent to a boundary between the first region and the second region.

18. The semiconductor device as claimed in claim 17, wherein the marking portion extends from the first region to the second region, and continuously crosses the boundary.

19. The semiconductor device as claimed in claim 12, wherein the patterned dummy layer and the first material layer comprise different materials.

20. The semiconductor device as claimed in claim 12, wherein the first material layer includes a conductive material, and the second material layer includes an oxide layer.
